(19) United States
(12) Patent Application Publication
(10) Pub. No.: US 2017/0288693 A1
(43) Pub. Date: Oct. 5, 2017

(54) CONTINUOUS TIME DELTA-SIGMA MODULATOR WITH A TIME INTERLEAVED QUANTIZATION FUNCTION

(71) Applicant: STMicroelectronics International N.V., Schiphol (NL)

(72) Inventors: Ashish Sharma Kumar, Ghaziabad (IN); Rajeev Jain, Greater Noida (IN); Chandrajit Debnath, Greater Noida (IN)

(73) Assignee: STMicroelectronics International N.V., Schiphol (NL)

(21) Appl. No.: 15/465,305

(22) Filed: Mar. 21, 2017

Related U.S. Application Data
(60) Provisional application No. 62/316,651, filed on Apr. 1, 2016.

(51) Int. Cl. H03M 3/00; H03M 1/00

(52) U.S. Cl. CPC H03M 3/464; H03M 1/001; H03M 3/466; H03M 3/42; H03M 3/494

(57) ABSTRACT

A wide band continuous time delta-sigma modulator implements a time interleaved quantization processing operation. The modulator may provide for an inherent finite impulse response filtering in the feedback loop. Additionally, further finite impulse response filtering in each time interleaved feedback path may be provided.

### CROSS REFERENCE TO RELATED APPLICATION

This application claims priority from United States Provisional Application for Patent No. 62/316,651 filed Apr. 1, 2016, the disclosure of which is incorporated by reference.

### TECHNICAL FIELD

The present invention relates to a continuous time delta-sigma modulator.

### BACKGROUND

Reference is made to FIG. 1 showing a block diagram for a prior art continuous time delta-sigma modulator 10. In FIG. 1, operations performed in the continuous time domain are indicated by signal lines with a narrower line width, while operations performed in the discrete digital domain are indicated by signal lines with a wider line width.

The modulator 10 includes an input 12 configured to receive an analog input signal x(t). The analog input signal x(t) is received at a first input of a summation circuit 14, and a second input of the summation circuit 14 receives an analog feedback signal fb(t). In a conventional operation, the summation circuit 14 functions to subtract the analog feedback signal fb(t) from the analog input signal x(t) to perform the “delta” function of the modulator and generate an analog signal q(t). The analog signal q(t) is applied to the input of a filter circuit 16 having a transfer function H_{L}(s) in the continuous time domain to perform the “sigma” function of the modulator. In an embodiment, the filter circuit 16 may, for example, comprise an analog integrator. The filter circuit 16 outputs an analog signal qc(t). A quantizer circuit 18 (i.e., an analog to digital converter) with a sampling function receives the analog signal qc(t), samples the analog value and converts the sampled analog value to an m-bit digital value with digital signal y(n), where m may be any desired integer value and n is the index for the sampling operation. In the illustrated example, m=4. The quantizer circuit 18 operates in response to a clock at a sampling frequency Fs. The digital signal y(n) is fed back to the input of a digital to analog converter 20, also operating at the sampling frequency Fs, which functions to convert the digital signal y(n) to the analog feedback signal fb(t) for application to the second input of the summation circuit 14.

Reference is made to FIG. 2 showing a block diagram for a prior art continuous time delta-sigma modulator 10′. In FIG. 2, operations performed in the continuous time domain are indicated by signal lines with a narrower line width, while operations performed in the discrete digital domain are indicated by signal lines with a wider line width. Like reference numbers refer to like or similar components. The modulator 10′ of FIG. 2 differs from the modulator 10 of FIG. 1 in that the feedback loop includes an N-tap finite impulse response filter 22 implementing the filter function of 1+Z⁻¹+ . . . +Z^{N-1}. The digital signal y(n) is received at the input of the filter 22, and the filter 22 outputs a filtered digital signal yf(n) to the input of the digital to analog converter 20. The digital to analog converter 20, operating at the sampling frequency Fs, functions to convert the filtered digital signal yf(n) to the analog feedback signal fb(t) for application to the second input of the summation circuit 14.

In an embodiment, the digital to analog converter 20 and finite impulse response filter 22 are a combined finite impulse response digital to analog converter (FIRDAC). See, for example, Putter, “ADC with finite impulse response feedback DAC,” Int. Solid State Circuits Conf., Dig. Tech. Papers, 2004, pp. 76-77 (incorporated by reference) and Shettigar, et al., “A 15 mW 3.6GS/s CT-ΣΔ ADC with 36 MHz bandwidth and 83 dB DR in 90 nm CMOS,” in IEEE Int. Solid-State Circuits Conf. (ISSCC) Dig. Tech. Papers, 2012, pp. 156-158 (incorporated by reference).

Reference is now made to FIG. 3 showing a block diagram of a prior art continuous time delta-sigma modulator 30 with a time interleaved quantization function. See, for example, Black, et al., “Time-interleaved converter arrays,” IEEE J. Solid-State Circuits, vol. 15, no. 12, pp. 1022-1029, December 1980 (incorporated by reference). In FIG. 3, operations performed in the continuous time domain are indicated by signal lines with a narrower line width, while operations performed in the discrete digital domain are indicated by signal lines with a wider line width.

The modulator 30 includes an input 32 configured to receive an analog input signal x(t). The analog input signal x(t) is received at a first input of a summation circuit 34, and a second input of the summation circuit 34 receives an analog feedback signal fb(t). In a conventional operation, the summation circuit 34 functions to subtract the analog feedback signal fb(t) from the analog input signal x(t) to perform the “delta” function of the modulator and generate an analog signal q(t). The analog signal q(t) is applied to the input of a filter circuit 36 having a transfer function H_{L}(s) in the continuous time domain to perform the “sigma” function of the modulator. In an embodiment, the filter circuit 36 may, for example, comprise an analog integrator. The filter circuit 36 outputs an analog signal qc(t).

The modulator 30 implements time interleaved quantization 45 and thus includes a plurality of quantizer circuits 38(1)-38(N). Each quantizer circuit 38 may, for example, comprise an analog to digital converter. Furthermore, each quantizer circuit 38 has a sampling function, with the sampling operation performed at a frequency of Fs/N, where N equals the number of quantizer circuits 38 and Fs is the frequency of the overall sampling clock (clk). The analog signal qc(t) is applied to an input of each quantizer circuit 38. Each quantizer circuit 38 functions to sample the analog value and converts the sampled analog value to an m-bit digital value as the digital signal yN(n), where m may be any desired integer value and n is the index for the sampling operation. In the illustrated example, m=4. While the frequency of the sampling clocks (clkN) for all quantizer circuits 38 generated by the clock circuit 44 is equal to Fs/N, the phases of the sampling clocks driving the quantizers 38(1) to 38(N) are offset from each other by 360/N degrees as shown in FIG. 4. Although the illustrated example is with N=3, it will be understood that N may be any selected integer value.

The digital signals y1(n)-yN(n) are applied to the inputs of a multiplexer circuit 42. The selection operation of the multiplexer circuit 42 is controlled to sequentially select the digital signals y1(n)-yN(n) to be fed back as digital signal y(n) to the input of a digital to analog converter 40 as shown in FIG. 4. The digital to analog converter 40 receives the clock (clk) at the sampling frequency Fs, and functions to convert the received digital signal y(n) to the analog feedback signal fb(t) for application to the second input of the summation circuit 34. The digital signal y(n) further comprises the digital output signal of the modulator circuit.

An advantage of this solution is that the clock rate for the modulator (analog to digital converter) circuit can be N times faster than with the solution of FIG. 1. Additionally, the bandwidth of the modulator circuit is N times wider than with the solution of FIG. 1.

Prior art continuous time delta-sigma modulators like that shown in FIGS. 1-2 are suitable candidates for many applications and advantageously are not power hungry circuits. However, bandwidths in excess of 100 MHz for some applications require a sampling frequency in the Gigahertz frequency range. Unfortunately, the maximum sampling frequency permitted with such circuits is limited by the latency of the quantizer.

There is a need in the art to provide a better solution.

### SUMMARY

In an embodiment, a delta-sigma modulator circuit comprises: an input configured to receive an analog input signal; a summation circuit configured to combine the analog input signal with an analog feedback signal to generate an analog output signal; a filter circuit configured to filter the analog output signal and generate a filtered analog signal; a plurality of time interleaved quantizer circuits, each quantizer circuit configured to receive the filtered analog signal and generate a corresponding digital signal; and a corresponding plurality of digital to analog converter circuits configured to receive corresponding ones of the digital signals from the time interleaved quantizer circuits and generate corresponding analog output signals that are combined to generate the analog feedback signal.

In an embodiment, a delta-sigma modulator circuit comprises: an input configured to receive an analog input signal; a summation circuit configured to combine the analog input signal with an analog feedback signal to generate an analog output signal; a filter circuit configured to filter the analog output signal and generate a filtered analog signal; a first quantizer circuit configured to receive the filtered analog signal and generate a first digital signal; a second quantizer circuit configured to receive the filtered analog signal and generate a second digital signal; wherein the first and second quantizer circuits operate in a time-interleaved manner; a first digital to analog converter circuit configured to receive the first digital signal and generate a first analog output signal; and a second digital to analog converter circuit configured to receive the second digital signal and generate a second analog output signal; wherein the first and second analog output signals combined form the analog feedback signal.

In an embodiment, a delta-sigma modulator circuit comprises: an input configured to receive an analog input signal; a summation circuit configured to combine the analog input signal with an analog feedback signal to generate an analog output signal; a filter circuit configured to filter the analog output signal and generate a filtered analog signal; a plurality of time interleaved quantizer circuits, each quantizer circuit configured to receive the filtered analog signal and generate a corresponding digital signal; a corresponding plurality of finite impulse response filters configured to receive corresponding ones of the digital signals from the time interleaved quantizer circuits and generate corresponding filtered digital signals; and a corresponding plurality of digital to analog converter circuits configured to receive corresponding ones of the filtered digital signals from the finite impulse response filters and generate corresponding analog output signals; wherein the analog output signals combined form the analog feedback signal.

### BRIEF DESCRIPTION OF THE DRAWINGS

For a better understanding of the embodiments, reference will now be made by way of example only to the accompanying figures in which:

FIG. 1 is a block diagram for a prior art continuous time delta-sigma modulator;

FIG. 2 is a block diagram for a prior art continuous time delta-sigma modulator;

FIG. 3 is a block diagram for a prior art continuous time delta-sigma modulator with a time interleaved quantization function;

FIG. 4 is a timing diagram for the modulator of FIG. 3;

FIG. 5 is a block diagram for a continuous time delta-sigma modulator with a time interleaved quantization function with an inherent finite impulse response filtering operation in the feedback path;

FIG. 6 is a timing diagram for the modulator of FIG. 5; and

FIG. 7 is a block diagram for a continuous time delta-sigma modulator including plural finite impulse response filters in the feedback path.

### DETAILED DESCRIPTION OF THE DRAWINGS

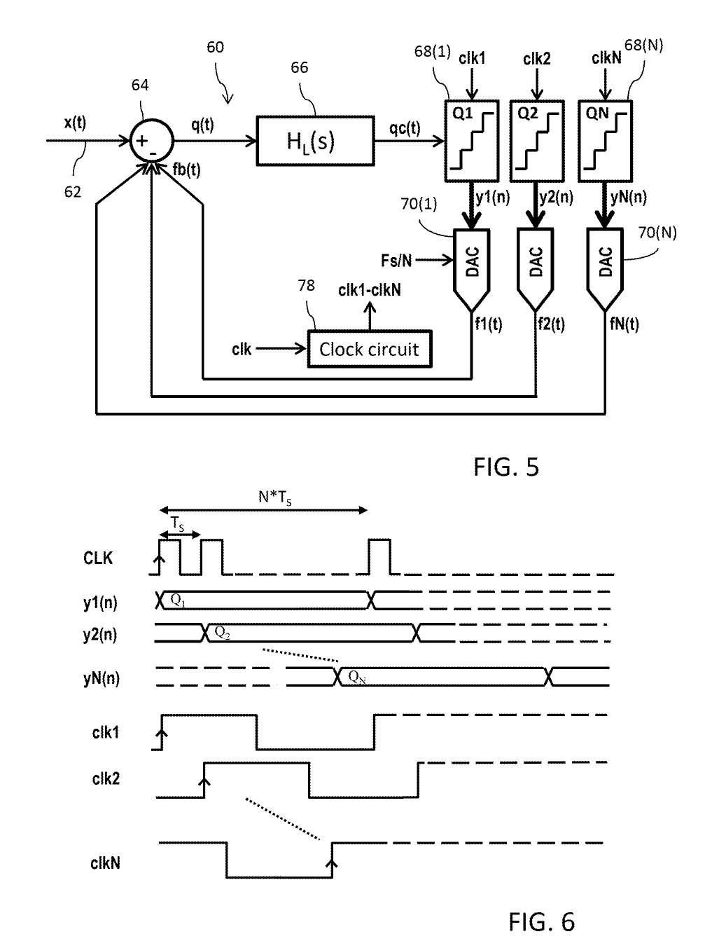

Reference is now made to FIG. 5 showing a block diagram for a continuous time delta-sigma modulator 60 with a time interleaved quantization function. In FIG. 5, operations performed in the continuous time domain are indicated by signal lines with a narrower line width, while operations performed in the discrete digital domain are indicated by signal lines with a wider line width.

The modulator 60 includes an input 62 configured to receive an analog input signal x(t). The analog input signal x(t) is received at a first input of a summation circuit 64, and a second input of the summation circuit 64 receives an analog feedback signal fb(t). In a conventional operation, the summation circuit 64 functions to subtract the analog feedback signal fb(t) from the analog input signal x(t) to perform the “delta” function of the modulator and generate an analog signal q(t). The analog signal q(t) is applied to the input of a filter circuit 66 having a transfer function H_{L}(s) in the continuous time domain to perform the “sigma” function of the modulator. In an embodiment, the filter circuit 66 may, for example, comprise an analog integrator. The filter circuit 66 outputs an analog signal qc(t).

The modulator 60 implements time interleaved quantization and thus includes a plurality of quantizer circuits 68(1)-68(N). Each quantizer circuit 68 may, for example, comprise an analog to digital converter. Furthermore, each quantizer circuit 68 has a sampling function, with the sampling operation performed at a frequency of Fs/N, where N equals the number of quantizer circuits 68 and Fs is the frequency of the overall sampling clock (clk). The analog signal qc(t) is applied to an input of each quantizer circuit 68. Each quantizer circuit 68 functions to sample the analog value and converts the sampled analog value to an m-bit digital value as the digital signal yN(n), where m may be any desired integer value and n is the index for the sampling operation. In the illustrated example, m=4. The frequency of the sampling clock (clkN) generated by the clock circuit 78 and applied to each quantizer circuit 68 is equal to Fs/N. However, the phases of the sampling clocks driving the quantizers 68(1) to 68(N) are offset from each other by 360/N degrees (see, FIG. 6). Although the illustrated example is with N=3, it will be understood that N may be any selected integer value.

The digital signals y1(n)-yN(n) are applied to corresponding inputs of a plurality of digital to analog converters 70(1)-70(N). Each digital to analog converter 70 operates at the frequency Fs/N and functions to convert the received digital signal yN(n) to the analog signal fN(t). The summation circuit 64 receives the analog signals f1(t)-fN(t) (which summed together form analog feedback signal fb(t)) for subtraction from the analog input signal x(t).

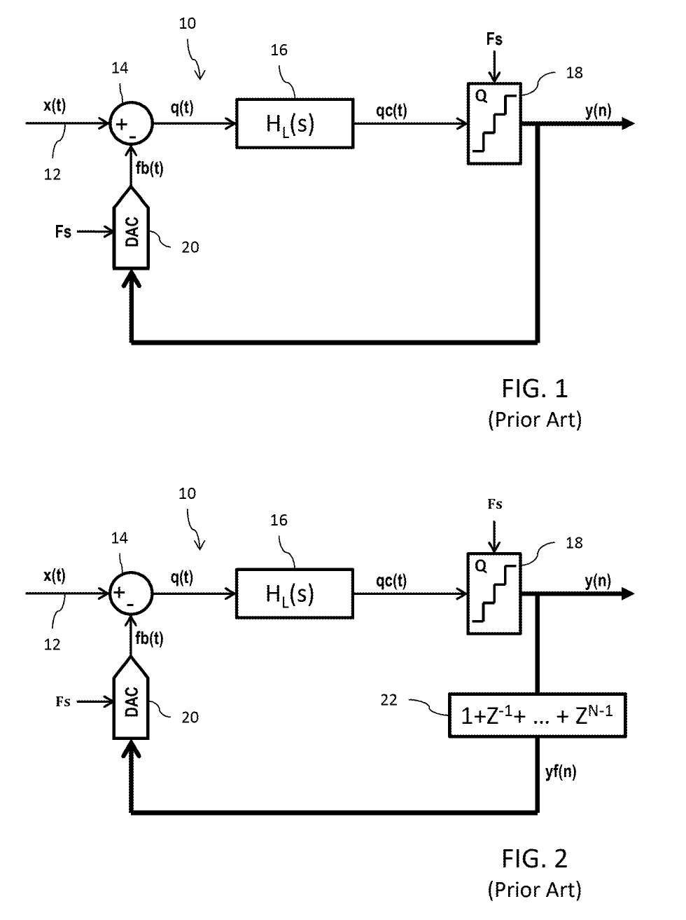

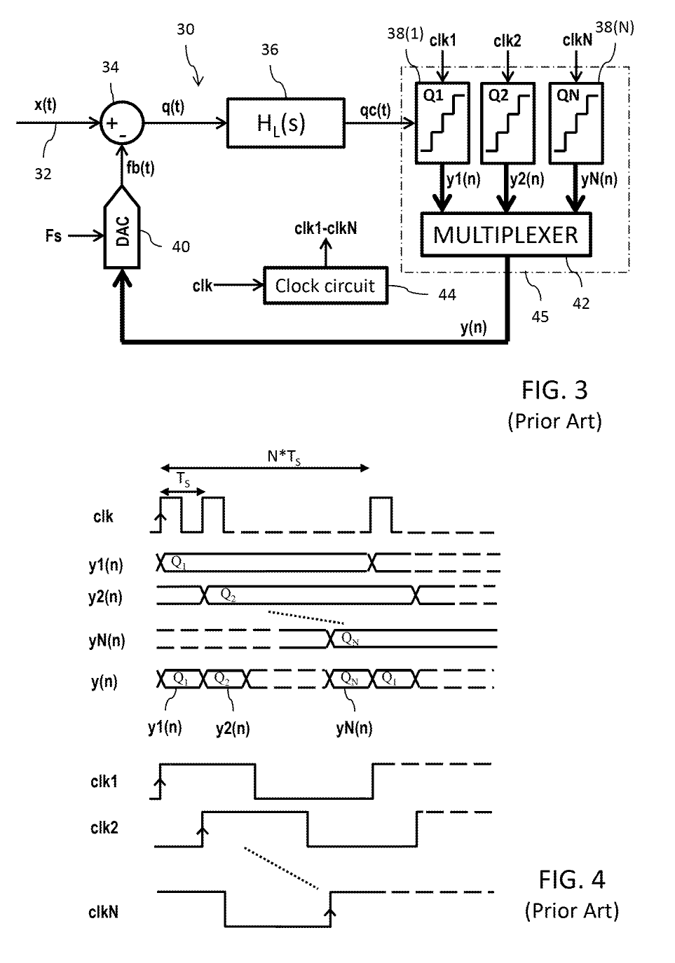

An advantage of this solution is that the clock rate for the modulator (analog to digital converter) circuit can be N times faster than with the prior art solution of FIGS. 1 and 2. Additionally, the bandwidth of the modulator circuit is N times wider than with the solution of FIGS. 1 and 2. A DAC is provided to correspond to each included quantizer and the DAC circuits advantageously operate at the slower frequency of Fs/N. Matching spurs between the N quantizers and the N DACs are suppressed by nulls present at multiples of Fs/N. Thus, the combination of the N quantizers and the N DACs in the manner of FIG. 5 presents an inherent filtering operation equivalent to an N-tap finite impulse response filter implementing a filter function of 1+Z⁻¹+ . . . +Z^{N-1}.

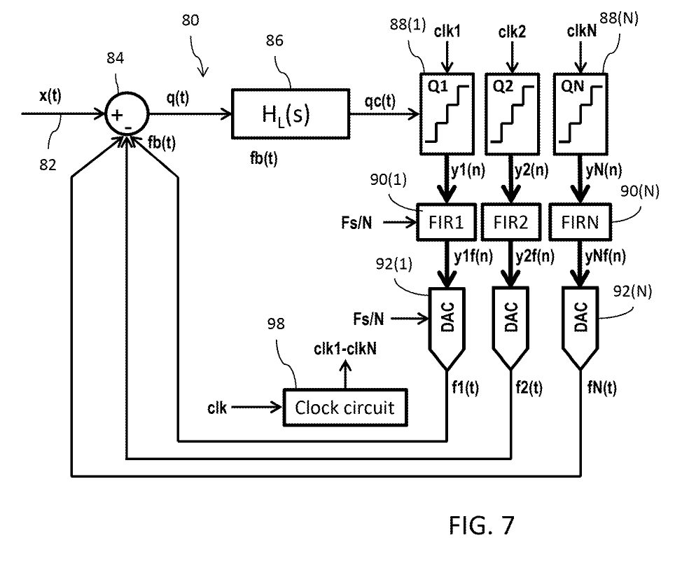

Reference is made to FIG. 7 showing a block diagram for a continuous time delta-sigma modulator 80 with a time interleaved quantization function. In FIG. 7, operations performed in the continuous time domain are indicated by signal lines with a narrower line width, while operations performed in the discrete digital domain are indicated by signal lines with a wider line width.

The modulator 80 includes an input 82 configured to receive an analog input signal x(t). The analog input signal x(t) is received at a first input of a summation circuit 84, and a second input of the summation circuit 84 receives an analog feedback signal fb(t). In a conventional operation, the summation circuit 84 functions to subtract the analog feedback signal fb(t) from the analog input signal x(t) to perform the “delta” function of the modulator and generate an analog signal q(t). The analog signal q(t) is applied to the input of a filter circuit 86 having a transfer function H_{L}(s) in the continuous time domain to perform the “sigma” function of the modulator. In an embodiment, the filter circuit 86 may, for example, comprise an analog integrator. The filter circuit 86 outputs an analog signal qc(t).

The modulator 80 implements time interleaved quantization and thus includes a plurality of quantizer circuits 88(1)-88(N). Each quantizer circuit 88 may, for example, comprise an analog to digital converter. Furthermore, each quantizer circuit 88 has a sampling function, with the sampling operation performed at a frequency of Fs/N, where N equals the number of quantizer circuits 88 and Fs is the frequency of the overall sampling clock (clk). The analog signal qc(t) is applied to an input of each quantizer circuit 88. Each quantizer circuit 88 functions to sample the analog value and converts the sampled analog value to an m-bit digital value as the digital signal yN(n), where m may be any desired integer value and n is the index for the sampling operation. In the illustrated example, m=4. The frequency of the sampling clock (clkN) generated by the clock circuit 98 and applied to each quantizer circuit 88 is equal to Fs/N. However, the phases of the sampling clocks driving the quantizers 88(1) to 88(N) are offset from each other by 360/N degrees (see, FIG. 6). Although the illustrated example is with N=3, it will be understood that N may be any selected integer value.

The digital signals y1(n)-yN(n) are applied to corresponding inputs of a plurality of finite impulse response filters (FIR1-FIRN) 90(1)-90(N). Each finite impulse response filter 90 is a K-tap finite impulse response filter operating at the frequency Fs/N to implement a particular filter function. The first impulse response filter (FIR1) may, for example, implement a K-tap filter function of 1+Z^{-N}+Z^{-2N}+ . . . . The second impulse response filter (FIR2) may, for example, implement a K-tap filter function of Z⁻¹+Z^{-N-1}+Z^{-2N-1}+ . . . . The N-th impulse response filter (FIRN) may, for example, implement a filter function of Z^{-(N-1)}+Z^{-(2N-1}+Z^{-(3N-1)}+ . . . . In each case, K is an integer value and K>N. The finite impulse response filters 90(1)-90(N) output corresponding filtered digital signals y1f(n)-yNf(n).

The filtered digital signals y1f(n)-yNf(n) are applied to corresponding inputs of a plurality of digital to analog converters 92(1)-92(N). Each digital to analog converter 92 operates at the frequency Fs/N and functions to convert the received digital signal yNf(n) to the analog signal fN(t). The summation circuit 84 receives the analog signals f1(t)-fN(t) (which summed together form analog feedback signal fb(t)) for subtraction from the analog input signal x(t).

As noted above, the solution of FIG. 5 presents an inherent filtering operation equivalent to an N-tap finite impulse response filter. An advantage of the solution of FIG. 7 in comparison to the solution of FIG. 5 is that the filter tap length is not restricted by the number N of time interleaved quantizers. In FIG. 7, any K-tap length FIR may be used for the finite impulse response filters 90, with the modulator operating using N-way time interleaved FIR filters at Fs/N.

Although implemented in the embodiments shown herein as a continuous time modulator, it will be understood that the disclosed processing is also applicable to discrete time modulators as well.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

1. A delta-sigma modulator circuit, comprising:
an input configured to receive an analog input signal;
a summation circuit configured to combine the analog input signal with an analog feedback signal to generate an analog output signal;
a filter circuit configured to filter the analog output signal and generate a filtered analog signal;
a plurality of time interleaved quantizer circuits, each quantizer circuit configured to receive the filtered analog signal and generate a corresponding digital signal; and
a corresponding plurality of digital to analog converter circuits configured to receive corresponding ones of the digital signals from the time interleaved quantizer circuits and generate corresponding analog output signals that are combined to generate the analog feedback signal.

2. The delta-sigma modulator circuit of claim 1, wherein a combined processing functionality of the plurality of time interleaved quantizer circuits and the plurality of digital to analog converter circuits provides an inherent filtering operation equivalent to a finite impulse response filter.

3. The delta-sigma modulator circuit of claim 2, wherein the plurality of time interleaved quantizer circuits comprises N time interleaved quantizer circuits, the corresponding plurality of digital to analog converter circuits comprises N digital to analog converter circuits, and the finite impulse response filter is an N-tap finite impulse response filter.

4. The delta-sigma modulator circuit of claim 3, further comprising a corresponding plurality of finite impulse response filters configured to receive corresponding ones of the digital signals from the time interleaved quantizer circuits and generate corresponding filtered digital signals, wherein said corresponding plurality of digital to analog converter circuits are configured to receive corresponding ones of the filtered digital signals.

5. The delta-sigma modulator circuit of claim 4, wherein each finite impulse response filter is a K-tap finite impulse response filter, wherein K>N.

6. A delta-sigma modulator circuit, comprising:
an input configured to receive an analog input signal;
a summation circuit configured to combine the analog input signal with an analog feedback signal to generate an analog output signal;
a filter circuit configured to filter the analog output signal and generate a filtered analog signal;
a first quantizer circuit configured to receive the filtered analog signal and generate a first digital signal;
a second quantizer circuit configured to receive the filtered analog signal and generate a second digital signal;
wherein the first and second quantizer circuits operate in a time-interleaved manner;
a first digital to analog converter circuit configured to receive the first digital signal and generate a first analog output signal; and
a second digital to analog converter circuit configured to receive the second digital signal and generate a second analog output signal;
wherein the first and second analog output signals combined form the analog feedback signal.

7. The delta-sigma modulator circuit of claim 6, wherein a combined processing functionality of the first and second quantizer circuits and the first and second analog converter circuits provides an inherent filtering operation equivalent to a finite impulse response filter.

8. The delta-sigma modulator circuit of claim 7, wherein the finite impulse response filter is at least a 2-tap finite impulse response filter.

9. The delta-sigma modulator circuit of claim 8, further comprising:
a first finite impulse response filter configured to receive the first digital signal and generate a first filtered digital signal; and
a second finite impulse response filter configured to receive the second digital signal and generate a second filtered digital signal;
wherein the first digital to analog converter circuit receives the first filtered digital signal and the second digital to analog converter circuit receives the second filtered digital signal.

10. The delta-sigma modulator circuit of claim 9, wherein each of the first and second finite impulse response filters is a K-tap finite impulse response filter, wherein K>2.

11. A delta-sigma modulator circuit, comprising:
an input configured to receive an analog input signal;
a summation circuit configured to combine the analog input signal with an analog feedback signal to generate an analog output signal;
a filter circuit configured to filter the analog output signal and generate a filtered analog signal;
a plurality of time interleaved quantizer circuits, each quantizer circuit configured to receive the filtered analog signal and generate a corresponding digital signal;
a corresponding plurality of finite impulse response filters configured to receive corresponding ones of the digital signals from the time interleaved quantizer circuits and generate corresponding filtered digital signals; and
a corresponding plurality of digital to analog converter circuits configured to receive corresponding ones of the filtered digital signals from the finite impulse response filters and generate corresponding analog output signals;
wherein the analog output signals combined form the analog feedback signal.

12. The delta-sigma modulator circuit of claim 11, wherein the plurality of time interleaved quantizer circuits comprises N time interleaved quantizer circuits, the corresponding plurality of finite impulse response filters comprises N finite impulse response filters, and the corresponding plurality of digital to analog converter circuits comprises N digital to analog converter circuits, and wherein each finite impulse response filter is a K-tap finite impulse response filter, wherein K>N.
